(19) United States
(12) Patent Application Publication
(10) Pub. No.: US 2025/0081812 A1
(43) Pub. Date: Mar. 6, 2025

(54) DISPLAY DEVICE AND METHOD OF MANUFACTURING THE SAME

(71) Applicant: Samsung Display Co., LTD., Yongin-si (KR)

(72) Inventors: Yu Jin KIM, Yongin-si (KR); Da Som KANG, Yongin-si (KR); Hong Min YOON, Yongin-si (KR)

(21) Appl. No.: 18/610,086

(22) Filed: Mar. 19, 2024

(30) Foreign Application Priority Data
Sep. 6, 2023 (KR) 10-2023-0118432

(51) Int. Cl. H10K 59/80; H10K 59/122; H10K 59/38

(52) U.S. Cl. CPC H10K 59/8723; H10K 59/122; H10K 59/38; H10K 59/873

(57) ABSTRACT

A display device includes a first layer which is on a first substrate including a display area and includes banks protruding in a thickness direction of the first substrate and a color conversion layer in an area surrounded by the banks and including a color conversion portion that includes quantum dots, a second layer on a second substrate facing the first substrate, a filling layer between the first layer and the second layer, and a plurality of edge spacers on an edge bank which is any one of the banks.

### CROSS-REFERENCE TO RELATED APPLICATION

The present application claims priority to and the benefit of Korean Patent Application No. 10-2023-0118432 filed, on Sep. 6, 2023, in the Korean Intellectual Property Office, the entire disclosure of which is incorporated by reference herein.

### BACKGROUND

### 1. Field

Embodiments of the present disclosure relate to a display device and a method of manufacturing the same.

### 2. Description of the Related Art

Recently, as interest in information displays has increased, and, for example, as the demand for high-quality display devices has increased, research and development on display devices has been continuously conducted.

The above information disclosed in this Background section is only for understanding of the background of the present disclosure, and, therefore, it may contain information that does not constitute prior art.

### SUMMARY

Embodiments of the present disclosure are directed to a display device that may be manufactured with improved reliability, and a method of manufacturing the same.

A display device according to an embodiment of the present disclosure includes a first layer on a first substrate including a display area and the first layer includes banks protruding in a thickness direction of the first substrate, a color conversion layer in an area surrounded by the banks, and a color conversion portion that includes quantum dots, a second layer on a second substrate facing the first substrate, a filling layer between the first layer and the second layer, and a plurality of edge spacers on an edge bank, which is any one of the banks.

The edge spacers may space the edge bank apart from the second layer.

The edge spacers may pass through the filling layer to support the second layer.

The first substrate may include a non-display area that does not overlap the display area, and the edge bank may surround the display area and be in the non-display area.

The edge spacers may be provided along an outer area of the edge bank.

The edge spacers may be provided along a first line on the edge bank and a second line spaced apart from the first line.

The banks may include an active bank in the display area, and active spacers may be on the active bank.

The active spacers and the edge spacers may be formed at substantially the same time point.

The active spacers and the edge spacers may include an acrylic-based material.

The color conversion layer may include a first insulating layer that caps the color conversion unit, the second layer may include a color filter layer including color filters and a second insulating layer that caps the color filters, and the filling layer may have one surface in contact with the first insulating layer and the other surface in contact with the second insulating layer.

The edge spacers may be in contact with the second insulating layer and the edge bank.

The first layer may further include a light-emitting element layer including a light-emitting element, and the color conversion layer may convert a wavelength of light emitted from the light-emitting element.

Another aspect of embodiments of the present disclosure relates to a method of manufacturing a display device. The method of manufacturing a display device according to an embodiment of the present disclosure includes forming a first layer on a first substrate including a display area, wherein the first layer includes banks protruding in a thickness direction of the first substrate, a color conversion layer in an area surrounded by the banks, and a color conversion portion that includes quantum dots, forming a plurality of edge spacers on an edge bank, which is one of the banks, forming a second layer on a second substrate facing the first substrate, and forming a filling layer between the first layer and the second layer to couple the first layer and the second layer.

The edge spacers may space the edge bank apart from the second layer.

The edge spacers may pass through the filling layer to support the second layer.

The first substrate may include a non-display area that does not overlap the display area, and the edge bank may surround the display area and may be in the non-display area.

The edge spacers may be formed along an outer area of the edge bank.

The banks may include an active bank in the display area, and active spacers may be formed on the active bank.

The active spacers and the edge spacers may be formed at substantially the same time point.

The active spacers and the edge spacers may include an acrylic-based material.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic plan view illustrating a display device according to an embodiment.

FIG. 2 is a schematic cross-sectional view illustrating a display device according to an embodiment.

FIG. 3 is a schematic cross-sectional view illustrating a display area of a display device according to an embodiment.

FIG. 4 is a schematic cross-sectional view illustrating an area in which a display area and a non-display area of a display device are adjacent to each other according to an embodiment.

FIG. 5 is a plan view illustrating an example of banks and spacers included in a display device.

FIG. 6 is a plan view illustrating another embodiment of banks and spacers included in a display device.

FIG. 7 is a flowchart illustrating a method of manufacturing a display device according to an embodiment.

FIGS. 8-11 are schematic cross-sectional views illustrating a method of manufacturing a display device according to an embodiment.

### DETAILED DESCRIPTION

It will be apparent to those skilled in the art that various modifications and variations can be made to the subject matter of the present disclosure without departing from the spirit or scope of the disclosure, and example embodiments are illustrated in the drawings and explained in the detailed description. However, it should be understood that this is not intended to limit the present disclosure to a specific disclosed form, and the present disclosure includes all modifications, equivalents, and substitutes included in the technical scope of the present disclosure.

Hereinafter, embodiments of the present disclosure will be described in more detail with reference to the accompanying drawings. In the following description, it should be noted that only portions relevant for comprehension of operations according to the present disclosure will be described and descriptions of other portions will be omitted to facilitate understanding of the subject matter of the present disclosure. The present disclosure is not limited to the following described embodiments but may also be embodied in other forms. Rather, these embodiments are provided so that the present disclosure will be thorough, and complete, and will fully convey the subject matter of the present disclosure to those skilled in the art.

Throughout the specification, it will be understood that when an element is referred to as being “coupled” or “connected” to another element, it can be directly coupled or connected to the other element or intervening elements may be present therebetween. The terminology used herein is for the purpose of describing example embodiments and is not intended to limit the present disclosure. Throughout the specification, unless explicitly described to the contrary, the word “comprise” and variations such as “comprises” or “comprising” will be understood to imply the inclusion of stated elements but not the exclusion of any other elements. “At least any one of X, Y, and Z” and “at least any one selected from the group consisting of X, Y, and Z” may be construed as each of X, Y, and Z or a combination of two or more of X, Y, and Z (for example, XYZ, XYY, YZ, and ZZ). As used herein, “and/or” includes one or more combinations of corresponding components.

It will be understood that, although the terms “first,” “second,” “third,” and so on may be used herein to describe various elements, these elements are not limited by these terms. These terms are used to distinguish one element from another element. Thus, a first element described below could also be termed as a second or third element without departing from the spirit and scope of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if the device in the drawings is turned over, elements described as “below” or “beneath” other elements or features would then be oriented “above” the other elements or features. Thus, in one embodiment, the term “below” can encompass both an orientation of above and below. Furthermore, the device may be otherwise oriented (e.g., rotated 90 degrees or at other orientations), and, as such, the spatially relative descriptors used herein should be interpreted accordingly.

Various embodiments are described with reference to drawings that may schematically illustrate idealized embodiments. Accordingly, it will be expected that the shapes may vary depending, for example, on tolerances and/or manufacturing techniques. Accordingly, the embodiments disclosed herein should not be construed as limited to the example shapes shown herein, but should be construed to include deviations in shapes that result from, for instance, manufacturing. As such, the shapes shown in the drawings may not depict the actual shapes of regions of the device, and the present embodiments are not limited thereto.

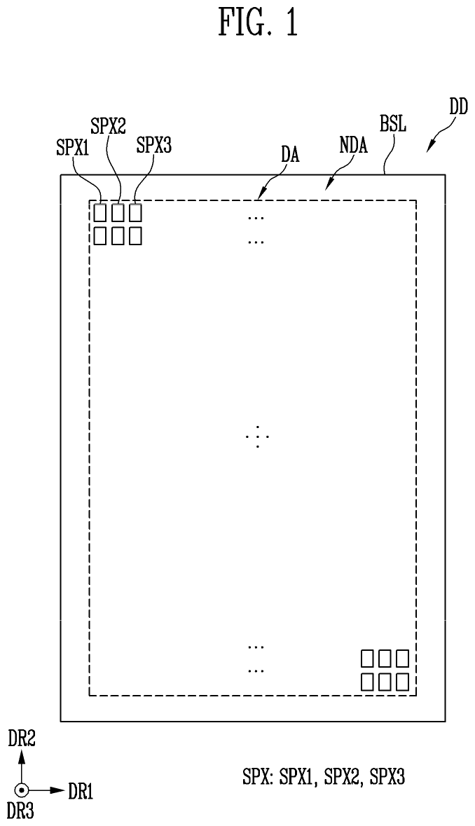

FIG. 1 is a schematic plan view illustrating a display device according to an embodiment.

Referring to FIG. 1, a display device DD may include a substrate BSL and subpixels SPX on the substrate BSL. The display device DD may further include a driving circuit unit (for example, a scan driver and a data driver) for driving the subpixels SPX, lines, and pads.

The display device DD (or the substrate BSL) may include a display area DA and a non-display area NDA. The non-display area NDA may refer to an area other than the display area DA. The non-display area NDA may surround at least a portion of the display area DA.

The substrate BSL may form a base surface of the display device DD. The substrate BSL may be a rigid or flexible substrate or film. For example, the substrate BSL may be a rigid substrate made of glass and/or tempered glass, a flexible substrate (or a thin film) made of plastic (or polymer), metal, and/or at least one insulating layer. The material and/or physical properties of the substrate BSL are not particularly limited. In embodiments, the substrate BSL may be substantially transparent. Here, the term “substantially transparent” may mean that light may be transmitted at a set or certain transmittance level or more. In other embodiments, the substrate BSL may be semi-transparent or opaque. According to embodiments, the substrate BSL may include a reflective material.

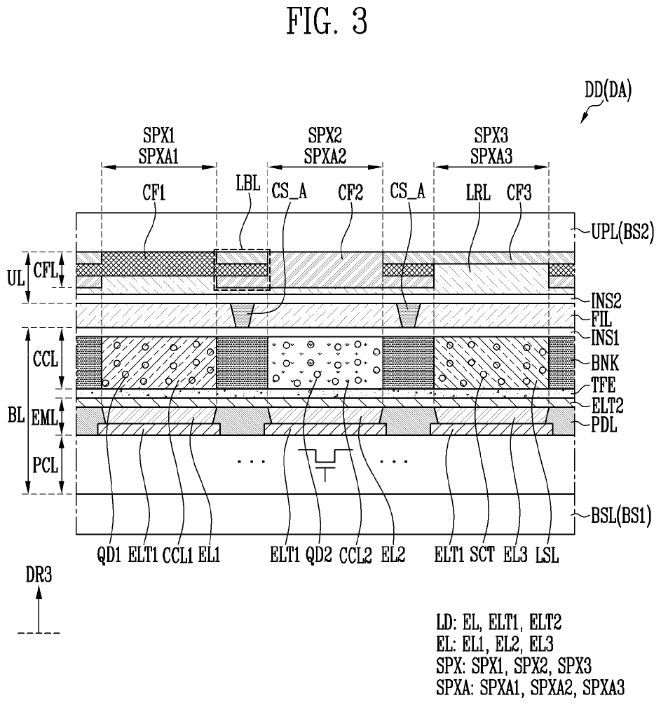

The substrate BSL may be a first substrate BS1 (shown in FIG. 3). For example, the first substrate BS1 may form a lower base.

The display area DA may refer to an area in which the subpixels SPX are provided. The non-display area NDA may refer to an area in which the subpixels SPX are not provided. The driving circuit unit, the lines, and the pads connected to the subpixels SPX of the display area DA may be in the non-display area NDA.

According to embodiments, the subpixels SPX may be provided according to a stripe or PENTILE® arrangement structure (e.g., an RGBG matrix, RGBG structure, or RGBG matrix structure), but the present disclosure is not limited thereto. PENTILE® is a duly registered trademark of Samsung Display Co., Ltd. Various embodiments may be applied to the present disclosure.

According to embodiments, the subpixels SPX may include a first subpixel SPX1, a second subpixel SPX2, and a third subpixel SPX3. The first subpixel SPX1, the second subpixel SPX2, and the third subpixel SPX3 may each be a subpixel. At least one first subpixel SPX1, at least one second subpixel SPX2, and at least one third subpixel SPX3 may form one pixel unit capable of emitting light having various suitable colors.

For example, each of the first subpixel SPX1, the second subpixel SPX2, and the third subpixel SPX3 may emit light having one color. For example, the first subpixel SPX1 may be a red pixel that emits light having a red color (for example, a first color), the second subpixel SPX2 may be a green pixel that emits light having a green color (for example, a second color), and the third subpixel SPX3 may be a blue pixel that emits light having a blue color (for example, a third color). According to embodiments, the number of second subpixels SPX2 may be greater than each of the number of first subpixel SPX1 and the number of third subpixels SX3. However, the colors, types (or kinds), and/or numbers of the first subpixel SPX1, the second subpixel SPX2, and the third subpixel SPX3 forming each pixel unit are not limited to specific examples.

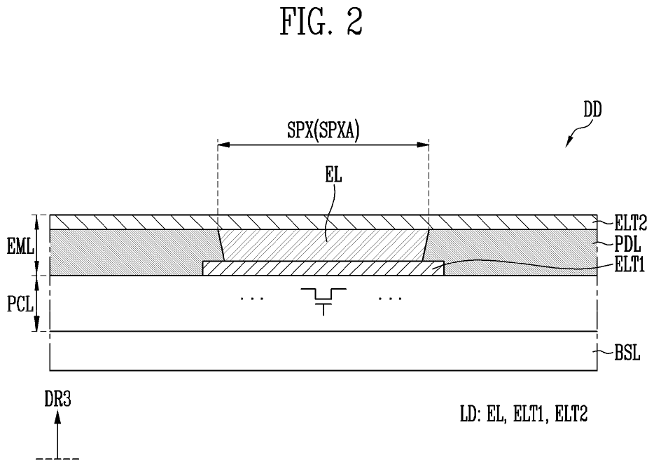

Next, a cross-sectional structure of the display device DD will be described with reference to FIG. 2. FIG. 2 is a schematic cross-sectional view illustrating a display device according to an embodiment.

Referring to FIG. 2, a display device DD may include a substrate BSL, a pixel circuit layer PCL, and a light-emitting element layer EML.

The substrate BSL may form a base on which the pixel circuit layer PCL and the light-emitting element layer EML are provided.

The pixel circuit layer PCL may be on the substrate BSL. The pixel circuit layer PCL may include a pixel circuit for driving light-emitting elements LD. The pixel circuit layer PCL may include conductive layers (e.g., electrically conductive layers) for forming pixel circuits and insulating layers (e.g., electrically insulating layers) between the conductive layers.

The pixel circuit may include a thin film transistor. The pixel circuit may include a driving transistor. The pixel circuit may be electrically connected to the light-emitting element LD to provide an electrical signal for allowing the light-emitting element LD to emit light.

The light-emitting element layer EML may be on the pixel circuit layer PCL. According to embodiments, the light-emitting element layer EML may include the light-emitting elements LD and a pixel definition layer PDL.

The light-emitting elements LD may include organic light-emitting diodes (OLEDs).

The light-emitting elements LD may be on the pixel circuit layer PCL. According to embodiments, the light-emitting elements LD may include a first electrode ELT1, an emission layer EL, and a second electrode ELT2. According to embodiments, the emission layer EL may be in an area defined by the pixel definition layer PDL. The pixel definition layer PDL may be adjacent to a periphery of the emission layer EL. One surface of the emission layer EL may be electrically connected to the first electrode ELT1, and the other surface of the emission layer EL may be electrically connected to the second electrode ELT2.

The first electrode ELT1 may be an anode with respect to the emission layer EL, and the second electrode ELT2 may be a common electrode (or a cathode) with respect to the emission layer EL. According to embodiments, the first electrode ELT1 and the second electrode ELT2 may include a conductive material (e.g., an electrically conductive material). For example, the first electrode ELT1 may include a conductive material (e.g., an electrically conductive material) having reflective properties, and the second electrode ELT2 may include a transparent conductive material (e.g., a transparent electrically conductive material). However, the present disclosure is not limited thereto.

The emission layer EL may have a multilayer thin film structure including a light generation layer. The emission layer EL may include a hole injection layer for injecting holes, a hole transport layer that has excellent hole transport properties and suppresses or reduces the movement of electrons not combined in the light generation layer to increase a probability of recombination between holes and electrons, the light generation layer that emits light through recombination between injected electrons and holes, a hole blocking layer for suppressing or reducing the movement of holes not combined in the light generation layer, an electron transport layer for smoothly transporting electrons to the light generation layer, and an electron injection layer for injecting electrons. The emission layer EL may emit light based on electrical signals provided from the first electrode ELT1 and the second electrode ELT2.

The emission layer EL may form one of the subpixels SPX. The emission layer EL may form a subpixel area SPXA from which light having one color is emitted. In a plan view, an area of the emission layer EL may correspond to the subpixel area SPXA. For example, each emission layer EL may correspond to each subpixel area SPXA.

The pixel definition layer PDL may be on the pixel circuit layer PCL to define a position at which the emission layer EL is provided. The pixel definition layer PDL may include an organic material. According to embodiments, the pixel definition layer PDL may include at least one selected from the group consisting of an acrylic resin, an epoxy resin, a phenol resin, a polyamide resin, and a polyimide resin. However, the present disclosure is not limited thereto.

In some embodiments, the insulating layer may be on the second electrode ELT2.

According to embodiments, the insulating layer may be a capping layer for the light-emitting element LD.

Next, a cross-sectional structure of a display device DD including a color conversion layer CCL in a display area DA according to an embodiment will be described with reference to FIG. 3. Contents that may overlap the above contents will be briefly described or not repeated.

FIG. 3 is a schematic cross-sectional view illustrating a display area of a display device according to an embodiment.

Referring to FIG. 3, a display device DD may include a first layer BL, a second layer UL, and a filling layer FIL between the first layer BL and the second layer UL. The first layer BL may be a lower layer of the display device DD. The second layer UL may be an upper layer of the display device DD.

The first layer BL and the second layer UL may be bonded to each other with the filling layer FL interposed therebetween. For example, after the first layer BL is formed and the second layer UL is formed, the filling layer FIL may be interposed between the first layer BL and the second layer UL, and then the first layer BL may be coupled to the second layer UL.

The first layer BL may include a pixel circuit layer PCL, a light-emitting element layer EML, an encapsulation layer TFE, and a color conversion layer CCL which are on the first substrate BS1.

The emission layer EL forming a light-emitting element LD may include a first emission layer EL1, a second emission layer EL2, and a third emission layer EL3.

For example, the display device DD may include subpixels SPX1, SPX2, and SPX3, each forming a subpixel area SPXA. The subpixel areas SPXA may include a first subpixel area SPXA1 which is formed by the first subpixel SPX1 and in which light having a first color is emitted, a second subpixel area SPXA2 which is formed by the second subpixel SPX2 and in which light having a second color is emitted, and a third subpixel area SPXA3 which is formed by the third subpixel SPX3 and in which light having a third color is emitted.

According to embodiments, the light-emitting element LD of the first subpixel SPX1 may include the first emission layer EL1. The light-emitting element LD of the second subpixel SPX2 may include the second emission layer EL2. The light-emitting element LD of the third subpixel SPX3 may include the third emission layer EL3.

According to embodiments, the first to third emission layers EL1, EL2, and EL3 may emit the light having the third color. However, the present disclosure is not necessarily limited thereto.

The color conversion layer CCL may be on the light-emitting element layer EML. The color conversion layer CCL may include a bank BNK, a first color conversion portion CCL1, a second color conversion portion CCL2, a scattering portion LSL (a light scattering portion LSL), and a first insulating layer INS1.

According to the display device DD according to the embodiment, the color conversion portions CCL1 and CCL2 and the scattering portion LSL corresponding to the colors of the first to third subpixels SPX1, SPX2, and SPX3 may display a full color image.

The encapsulation layer TFE may be on the light-emitting element layer EML. When the encapsulation layer TFE is in the form of an encapsulation film, the encapsulation layer TFE may include an inorganic film and/or an organic film.

The bank BNK may be on the encapsulation layer TFE. The bank BNK may be in contact with the encapsulation layer TFE. For example, the bank BNK may be patterned on the encapsulation layer TFE.

The bank BNK may protrude in a thickness direction (for example, a third direction DR3) of the substrate BSL and may surround one area. For example, the bank BNK may surround an area in which the color conversion portions CCL1 and CCL2 and/or the scattering portion LSL are provided. The bank BNK may define the area in which the color conversion portions CCL1 and CCL2 or the scattering portion LSL is provided.

The bank BNK may be patterned during a process of forming the first layer BL based on the first substrate BS1. Accordingly, the bank BNK may be below the filling layer FIL. For example, the bank BNK may be between the filling layer FIL and the light-emitting element layer EML.

The bank BNK may include an organic material. For example, the bank BNK may include at least one selected from the group consisting of an acrylic resin, an epoxy resin, a phenol resin, a polyamide resin, and a polyimide resin. However, the present disclosure is not limited thereto.

The color conversion portions CCL1 and CCL2 may be configured to change a wavelength of light. The color conversion portions CCL1 and CCL2 and the scattering portion LSL may be on the light-emitting element layer EML. The color conversion portions CCL1 and CCL2 and the scattering portion LSL may be below color filters CF1, CF2, and CF3. The color conversion portions CCL1 and CCL2 and the scattering portion LSL may be between the color filters CF1, CF2, and CF3 and the light-emitting element layer EML. The color conversion portions CCL1 and CCL2 and the scattering portion LSL may be provided (or patterned) in an area surrounded by the bank BNK protruding in the thickness direction (for example, the third direction DR3) of the substrate BSL.

The first color conversion portion CCL1 may include first color conversion particles that convert the light having the third color (for example, a blue color) emitted from a blue emission layer BEL into the light having the first color (for example, a red light). For example, the first color conversion portion CCL1 may include a plurality of first quantum dots QD1 dispersed in a matrix material such as a base resin. The first quantum dots QD1 may absorb blue light and shift a wavelength of the light according to an energy transition to emit red light.

The second color conversion portion CCL2 may include second color conversion particles that convert the light having the third color (for example, a blue color) emitted from the blue emission layer BEL into the light having the second color (for example, a green light). For example, the second color conversion portion CCL2 may include a plurality of second quantum dots QD2 dispersed in a matrix material such as a base resin. The second quantum dots QD2 may absorb blue light and shift a wavelength length of the light according to an energy transition to emit green light.

In an embodiment, blue light having a relatively short wavelength in a visible light region may be incident on each of the first quantum dots QD1 and the second quantum dot QD2, thereby increasing an absorption coefficient of the first quantum dots QD1 and the second quantum dots QD2. Accordingly, the efficiency of light emitted from the first subpixel SPX1 and the second subpixel SPX2 can be improved and concurrently (e.g., simultaneously), excellent color reproduction can be secured.

The scattering portion LSL may be provided to efficiently use the light having the third color (or a blue color) emitted from the blue emission layer BEL. For example, the scattering portion LSL may include a scattering body SCT (e.g., a light scattering body SCT). As an example, the scattering body SCT of the scattering portion LSL may include various suitable light scattering particles and/or light scattering materials. For example, the scattering body may include at least one selected from the group of silica (SiOₓ) (for example, a silica bead or hollow silica), titanium oxide (TiOₓ), zirconium oxide (ZrOₓ), aluminum oxide (AlₓO_{y}), indium oxide (InₓO_{y}), zinc oxide (ZnO), tin oxide (SnOₓ), and antimony oxide (SbₓO_{y}). However, the present disclosure is not limited thereto. In some embodiments, the scattering body SCT may not be only in the third subpixel SPX3 and may be optionally included in the first color conversion portion CCL1 or the second color conversion portion CCL2. According to embodiments, the scattering body SCT may be omitted, and thus the scattering portion LSL made of a transparent polymer may be provided.

The first insulating layer INS1 may be on the bank BNK, the color conversion portions CCL1 and CCL2, and the scattering portion LSL. The first insulating layer INS1 may be a capping layer for the color conversion layer CCL.

The first insulating layer INS1 may include an inorganic material. The inorganic material may include at least one selected from the group consisting of silicon nitride (SiNₓ), silicon oxide (SiOₓ), silicon oxynitride (SiOₓN_{y}), and aluminum oxide (AlₓO_{y}). However, the present disclosure is not limited thereto.

The filling layer FIL may be between the first layer BL and the second layer UL. For example, the filling layer FIL may be between a color filter layer CFL and the color conversion layer CCL. The filling layer FIL may be between the first insulating layer INS1 and a second insulating layer INS2.

The filling layer FIL may fill a space between the first layer BL and the second layer UL. The filling layer FIL may include a material capable of transmitting light. For example, the filling layer FIL may include a silicon-based organic material, an epoxy-based organic material, and/or an epoxy-acrylic-based organic material. However, the present disclosure is not limited thereto, and the filling layer FIL may include various suitable materials.

One surface of the filling layer FIL may be covered by the first insulating layer INS1, and the other surface of the filling layer FIL may be covered by the second insulating layer INS2. One surface of the filling layer FIL may be in contact with the first insulating layer INS1, and the other surface of the filling layer FIL may be in contact with the second insulating layer INS2.

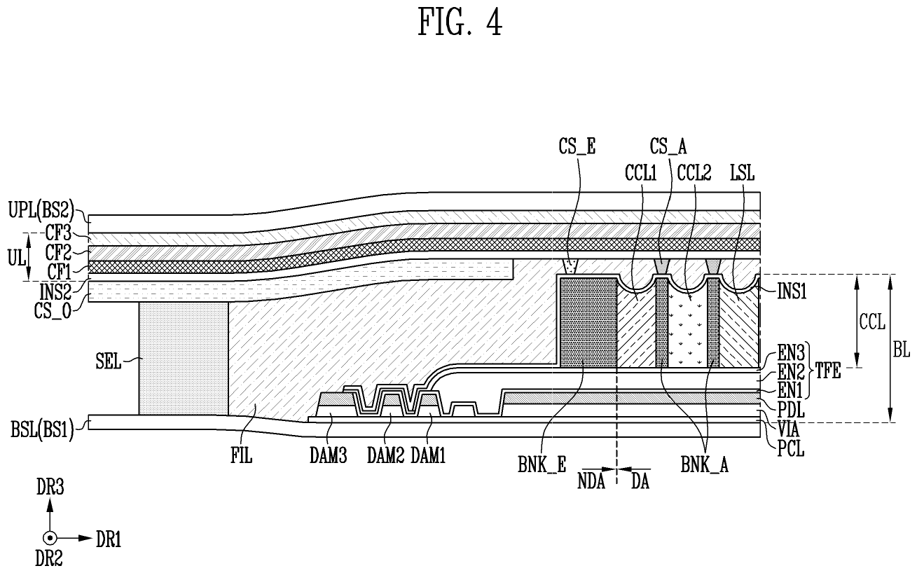

Spacers CS may include active spacers CS_A, edge spacers CS_E (see FIG. 4), and outer spacers CS_O (see FIG. 4). The spacers CS may be between the first layer BL and the second layer UL. Accordingly, the spacers CS may prevent (or reduce a likelihood or degree of) collision of the first layer BL and the second layer UL with each other when the first layer BL and the second layer UL are coupled to each other.

The spacers CS may include an organic material. According to embodiments, the spacers CS may include an acrylic material. However, this is merely an example, and the present disclosure is not limited thereto.

The active spacers CS_A may be between the first insulating layer INS1 and the second insulating layer INS2. For example, the active spacers CS_A may be on the first insulating layer INS1 to separate the first insulating layer INS1 from the second insulating layer INS2.

The second layer UL may include one or more layers on a second substrate BS2. For example, the second layer UL may include the second substrate BS2 and a color filter layer CFL.

The color filter layer CFL may be on the filling layer FIL. The color filter layer CFL may include a first color filter CF1, a second color filter CF2, and a third color filter CF3.

The second insulating layer INS2 may be on the filling layer FIL. The second insulating layer INS2 may be a capping layer for the color filter layer CFL and a low refractive index layer LRL.

The second insulating layer INS2 may include an inorganic material. The inorganic material may include at least one selected from the group consisting of silicon nitride (SiNₓ), silicon oxide (SiOₓ), silicon oxynitride (SiOₓN_{y}), and aluminum oxide (AlₓO_{y}). However, the present disclosure is not limited thereto.

The low refractive index layer LRL may be on the second insulating layer INS2. For example, the low refractive index layer LRL may be between the second insulating layer INS2 and the color filters CF1, CF2, and CF3.

The low refractive index layer LRL may have a relatively low refractive index as compared with the color conversion layer CCL. Accordingly, the low refractive index layer LRL may totally reflect light emitted from the color conversion layer CCL, thereby improving the light emission efficiency of the subpixels SPX. For example, the low refractive index layer LRL may totally reflect light, which is emitted from the color conversion layer CCL and travels, in an oblique direction.

The color filters CF1, CF2, and CF3 may selectively transmit light having one color. According to embodiments, a full-color image may be displayed by providing the color filters CF1, CF2, and CF3 respectively corresponding to colors of the first to third subpixels SPX1, SPX2, and SPX3.

The first color filter CF1 may be a color filter for forming the first subpixel SPX1 and may overlap the first subpixel area SPXA1 when viewed from above. The first color filter CF1 may selectively transmit the light having the first color. The first color filter CF1 may be a red color filter and may include a red color filter material.

The second color filter CF2 may be a color filter for forming the second subpixel SPX2 and may overlap the second subpixel area SPXA2 when viewed from above. The second color filter CF2 may selectively transmit the light having the second color. The second color filter CF2 may be a green color filter and may include a green color filter material.

The third color filter CF3 may be a color filter for forming the third subpixel SPX3 and may overlap the third subpixel area SPXA3 when viewed from above. The third color filter CF3 may selectively transmit the light having the third color. The third color filter CF3 may be a blue color filter and may include a blue color filter material.

According to embodiments, the first to third color filters CF1, CF2, and CF3 may overlap each other when viewed from above and form a light blocking layer LBL. The light blocking layer LBL may be between the subpixel areas SPXA. However, the present disclosure is not necessarily limited thereto, and according to embodiments, a separate light blocking material may be between the subpixel areas SPXA to form the light blocking layer LBL.

An upper substrate UPL may be on the color filter layer CFL. The upper substrate UPL may form a base for patterning one or more layers when forming the second layer UL.

The upper substrate UPL may be the second substrate BS2. For example, the second substrate BS2 may form an upper base. The second substrate BS2 may be spaced apart from the first substrate BS1 in the third direction DR3 and may face the first substrate BS1.

The upper substrate UPL may include at least one of the materials described above with reference to the substrate BSL. The upper substrate UPL may include the same material as the substrate BSL. However, the present disclosure is not limited thereto, and the upper substrate UPL may include a different material from the substrate BSL.

Next, with reference to FIG. 4, a cross-sectional structure of a display device DD including a color conversion layer CCL according to an embodiment will be described in an area in which a display area DA and a non-display area NDA are adjacent to each other. Contents that may overlap the above contents will be briefly described or not repeated.

FIG. 4 is a schematic cross-sectional view illustrating an area in which a display area and a non-display area of a display device are adjacent to each other according to an embodiment.

Referring to FIG. 4, a lower substrate BSL, an upper substrate UPL, and a filling layer FIL may be on a display area DA and a non-display area NDA.

A via layer VIA may be on a pixel circuit layer PCL. For example, the via layer VIA may be an organic planarization layer that may cover and planarize pixel circuit elements of the pixel circuit layer PCL. According to embodiments, the via layer VIA may be an inorganic insulating film including an inorganic material. A pixel definition layer PDL may be provided and/or formed on the via layer VIA.

An encapsulation layer TFE may be on the pixel definition layer PDL. The encapsulation layer TFE may include first to third encapsulation layers EN to EN3 sequentially in a third direction DR3.

The first encapsulation layer EN1 and the third encapsulation layer EN3 may be inorganic layers including an inorganic material, and the second encapsulation layer EN2 may be an organic layer including an organic material. The first encapsulation layer EN1 and the third encapsulation layer EN3 may protect the subpixels SPX from moisture and oxygen. The second encapsulation layer EN2 may protect the subpixels SPX from foreign materials such as dust particles.

The color conversion layer CCL may be on the encapsulation layer TFE. The color conversion layer CCL may be spaced apart from a second substrate BS2. For example, the color conversion layer CCL may not be in contact with a second insulating layer INS2.

The bank BNK may include an edge bank BNK_E and an active bank BNK_A. The edge bank (BNK_E) may be placed on the non-display area (NDA). For example, the edge bank BNK_E may surround the display area DA and may be on the non-display area NDA. The active bank BNK_A may be on the display area DA. For example, the active bank BNK_A may be a bank (BNK) pattern on the display area DA.

A plurality of dam structures DAM1 to DAM3 may be placed in the non-display area NDA. For example, first to third dam structures DAM1 to DAM3 may be on a first substrate BS1 to be sequentially spaced apart from the display area DA. In FIG. 4, the dam structures are illustrated as being provided as three dam structures, but the present disclosure is not limited thereto.

The first to third dam structures DAM1 to DAM3 may have a cross section having a trapezoidal shape in which a width gradually decreases upward in the third direction DR3, but a shape thereof is not limited as long as the shape may prevent or reduce overflow of the second encapsulation layer EN2 into the non-display area NDA spaced apart from the display area DA by a set or certain distance.

A sealing portion SEL may be in the non-display area NDA. The sealing portion SEL may be provided along an outer edge of the display device DD. For example, the sealing portion SEL may surround the non-display area NDA and the display area DA. The sealing portion SEL may include a material in which a sealant is cured. For example, the sealant may include an ultraviolet (UV)-curable material and/or a heat-curable material, and according to embodiments, the sealant may include at least one selected from the group consisting of a silicone-based resin, an epoxy-based resin, an acrylic-based resin, and a polyimide-based resin. However, the present disclosure is not necessarily limited thereto.

An outer spacer CS_O may be on the sealing portion SEL. The outer spacer CS_0 may be on the sealing portion SEL to support a second layer UL. For example, the outer spacer CS_0 may be on the sealing portion SEL to be in contact with a second insulating layer INS2. Accordingly, the outer spacer CS_0 may fill a gap that may be present between the sealing portion SEL and the second layer UL.

Edge spacers CS_E and active spacers CS_A may be on the color conversion layer CCL. For example, the edge spacers CS_E and the active spacers CS_A may be on a first insulating layer INS1.

The edge spacers CS_E and the active spacers CS_A may overlap the bank BNK. For example, the edge spacers CS_E may overlap the edge bank BNK_E, and the active spacers CS_A may overlap the active bank BNK_A.

The edge spacers CS_E and the active spacers CS_A may have a cross section having an inverted trapezoidal shape. For example, the edge spacers CS_E and the active spacers CS_A may have the cross-section having the inverted trapezoid in which a width increases upward in the third direction DR3. However, the shape is not limited as long as the shape may support the second layer UL.

In some embodiments, the filling layer FIL may fill an empty space present between a first layer BL and the second layer UL by the edge spacers CS_E. For example, when the first layer BL and the second layer UL are coupled, the edge spacers CS_E may maintain a state in which the edge bank BNK_E and the second layer UL are spaced apart from each other. Accordingly, a filler may stably flow from the display area DA to the non-display area NDA through a separation space between the edge bank BNK_E and the second layer UL. For example, the filler may flow in a direction opposite to a first direction DR1, and thus the filling layer FIL may be formed to fill the entire empty space between the first layer BL and the second layer UL.

In embodiments in which a structure for supporting an upper layer is not present on the edge bank, when a lower layer and the upper layer are coupled, the edge bank and the upper layer may be in contact with each other. Accordingly, a separation space may not be present between the edge bank and the upper layer. In some embodiments, the filler may not spread to an edge of the display device, and thus an empty space in which a filling layer is not formed may be present between the upper layer and the lower layer. When a space in which a filling layer is not formed is present, there may be a risk of moisture permeating into the space during a display device manufacturing process.

In some embodiments, when an empty space in which a filling layer is not formed is present between the upper layer and the lower layer, a coupling force between the upper layer and the lower layer may be reduced. For example, a coupling between the upper layer and the lower layer may be maintained by the adhesive strength of the filling layer. In some embodiments, when a space in which a filling layer is not present is present, the coupling force between the upper layer and the lower layer may be weakened, and thus the upper layer and the lower layer may be separated. For example, a resilience for the upper and lower layers may occur in the non-display area, and there may be a risk of damage to at least a portion of each layer.

According to embodiments of the present disclosure, the edge spacers CS_E may be on the edge bank BNK_E. Accordingly, the filling layer FIL may be formed to fill the entire empty space between the first layer BL and the second layer UL, and a risk of moisture permeation into the space between the first layer BL and the second layer (UL) and/or a risk of damage to a portion of each of the first layer BL and the second layer UL may be minimized or at least reduced. Accordingly, the reliability of a process of manufacturing the display device DD may be improved.

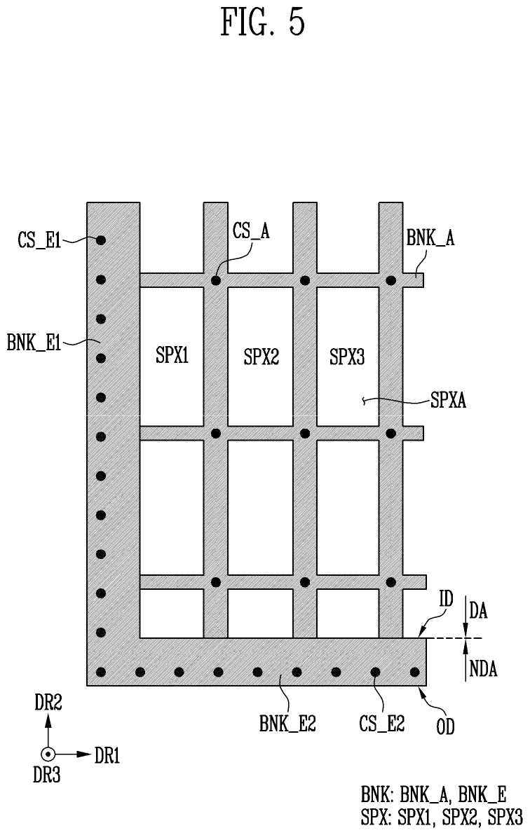

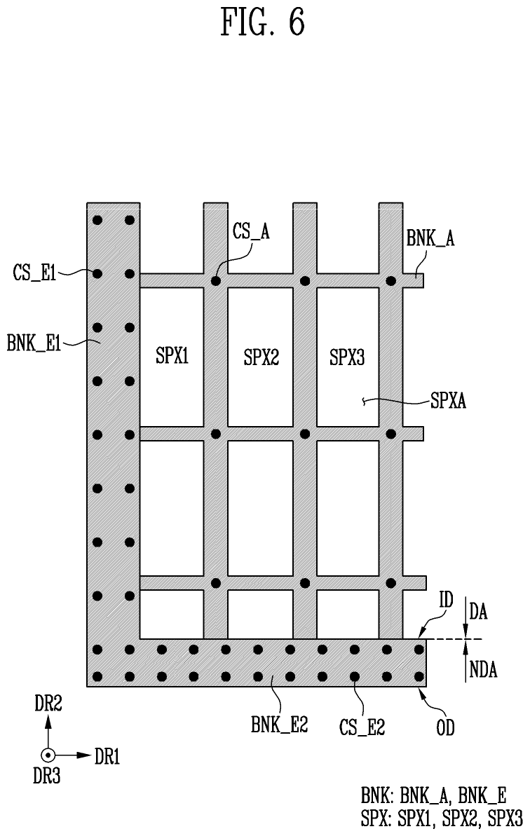

FIG. 5 is a plan view illustrating an example of banks and spacers included in a display device. FIG. 6 is a plan view illustrating another embodiment of banks and spacers included in a display device.

In FIGS. 5-6, only a portion of a bank BNK is schematically illustrated for convenience of description.

Referring to FIGS. 1 and 5-6, a display device DD may include a bank BNK to form subpixels SPX.

The bank BNK may extend in a first direction DR1 and a second direction DR2 that intersects the first direction DR1. The bank BNK may partition subpixel areas SPXA of subpixels SPX. The light-emitting elements LD may be in an opening of the bank BNK. For example, a portion at which the bank BNK is positioned may be a non-emission area, and the opening of the bank BNK may be the subpixel area SPXA.

An edge bank BNK_E may be an edge area of the bank BNK. For example, the edge bank BNK_E may be a structure surrounding a display area DA.

The edge bank BNK_E may define a boundary between the display area DA and a non-display area NDA. For example, the edge bank BNK_E may include an inner surface ID that overlaps an imaginary line present at the boundary between the display area DA and the non-display area NDA, and an outer surface OD opposite to the inner surface ID in a direction opposite to a second direction DR2. Accordingly, the inner surface ID of the edge bank BNK_E may define the boundary between the display area DA and the non-display area NDA.

The edge bank BNK_E may include a first edge bank BNK_E1 and a second edge bank BNK_E2. The first edge bank BNK_E1 may be in the second direction DR2, and the second edge bank BNK_E2 may be in the first direction DR1.

The edge spacers CS_E may include first edge spacers CS_E1 and second edge spacers CS_E2. The first edge spacers CS_E1 may be on the first edge bank BNK_E1, and the second edge spacers CS_E2 may be placed on the second edge bank BNK_E2. For example, the first edge spacers CS_E1 may be on the first edge bank BNK_E1 in the second direction DR2, and the second edge spacers CS_E2 may be on the second edge bank BNK_E2 in the first direction DR1.

The edge spacers CS_E may have a circular shape in a plan view. According to embodiments, the edge spacers CS_E may have a polygonal shape in a plan view. For example, the edge spacers CS_E may have a triangular or quadrangular shape, and a shape there is not limited thereto as long as the shape may stably support a second layer UL (see FIG. 4) on the bank BNK.

The edge spacers CS_E may be provided along an outer area of the edge bank BNK_E. The outer area may be an area of the edge bank BNK_E that is closer to the outer surface OD than the inner surface ID of the edge bank BNK_E. Accordingly, the edge spacers CS_E may be on the edge bank BNK_E to be closer to the outer surface OD than the inner surface ID of the edge bank BNK_E. For example, the second edge spacers CS_E2 may be provided in the first direction DR1 to be close to the outer surface OD of the edge bank BNK_E.

The active bank BNK_A may be in a set or certain pattern in the display area DA. For example, the active bank BNK_A may have a grid-shaped pattern in the display area DA.

The active spacers CS_A may be on the active bank BNK_A. For example, the active spacers CS_A may be on the active bank BNK_A in the first direction DR1 and/or the second direction DR2.

According to embodiments, the active spacers CS_A may be in intersection areas between patterns of the active bank BNK_A. For example, the active bank BNK_A may include first portions extending in the first direction DR1 and second portions extending in the second direction DR2. The active spacers CS_A may be in intersection areas between the first portions and the second portions of the active bank BNK_A.

Referring to FIG. 6, the edge spacers CS_E may be provided in two or more lines. For example, the edge spacers CS_E may be provided in two or more rows or columns. For example, the first edge spacers CS_E1 may be on the first edge bank BNK_E1 in two or more columns (for example, vertical lines), and the second edge spacers CS_E2 may be on the second edge bank BNK_E2 in two or more rows (for example, horizontal lines). In FIG. 6, the edge spacers CS_E are illustrated as be being provided in two rows or columns, but the present disclosure is not limited thereto.

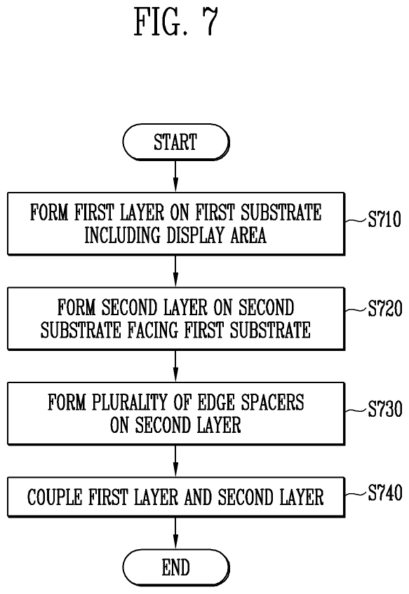

Next, a method of manufacturing a display device DD according to an embodiment will be described with reference to FIGS. 7-11. Content that may overlap with the foregoing content is briefly explained or not repeated.

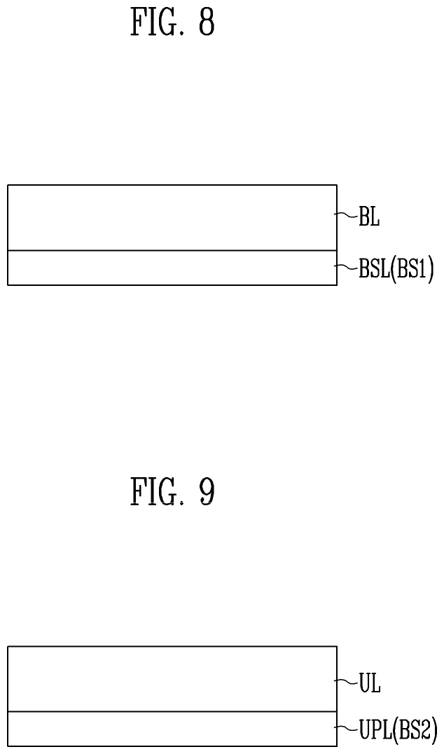

FIG. 7 is a flowchart illustrating a method of manufacturing a display device according to an embodiment. FIGS. 8-11 are schematic cross-sectional views illustrating the method of manufacturing a display device according to the embodiment.

Referring to FIG. 7, a method of manufacturing a display device DD may include forming a first layer on a first substrate including a display area (S710), forming a second layer on a second substrate facing the first substrate (S720), forming a plurality of edge spacers on the second layer (S730), and coupling the first layer and the second layer (S740).

Referring to FIGS. 3 and 7-8, in S710, a first substrate BS1 may be prepared, and a first layer BL may be on the first substrate BS1.

In the present operation, materials for forming a pixel circuit layer PCL, a light-emitting element layer EML, and a color conversion layer CCL may be patterned on the first substrate BS1.

In the present specification, conductive layers (e.g., electrically conductive layers) and insulating layers (e.g., electrically insulating layers) may be formed through any suitable patterning process (for example, a photolithography process) using a mask that is generally used in the art.

In the present operation, when the light-emitting element layer EML are formed, after a second electrode ELT2 is patterned, an insulating layer for capping light-emitting elements LD may be formed. An encapsulation layer TFE may be formed on a corresponding insulating layer, and a bank BNK may be patterned on the encapsulation layer TFE. The bank BNK may include an organic material and may be patterned to cover the pixel circuit layer PCL and the light-emitting element layer EML. After the bank BNK is patterned, color conversion portions CCL1 and CCL2 and a scattering portion LSL (e.g., a light scattering portion LSL) may be patterned.

Referring to FIGS. 7 and 9, in S720, a second substrate BS2 may be prepared, and a second layer UL may be on the second substrate BS2.

In the present operation, materials for forming a color filter layer CFL may be patterned on the second substrate BS2. In some embodiments, one or more layers described above with reference to FIG. 3 may be on the second substrate BS2. For example, the color filter layer CFL and a low refractive index layer LRL may be formed, and then a second insulating layer INS2 may be formed.

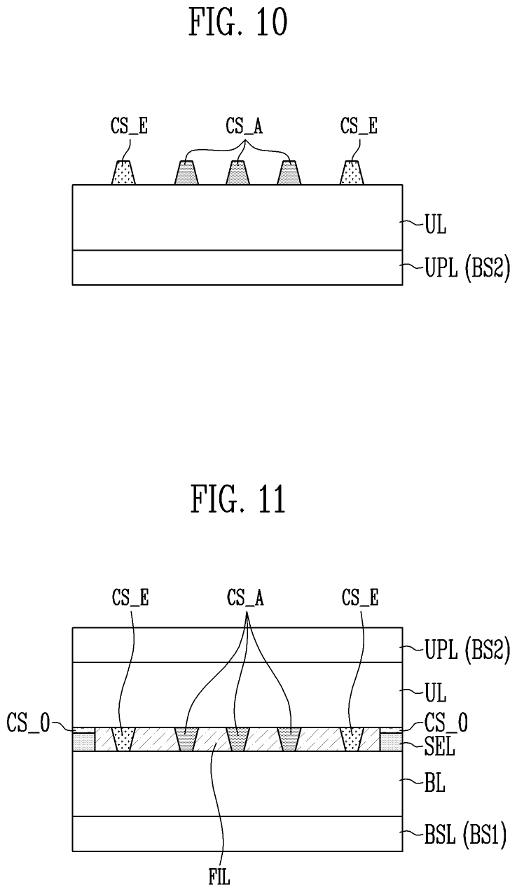

Referring to FIGS. 7 and 10, in S730, a plurality of edge spacers CS_E may be formed on the second layer UL.

Referring to FIG. 4 together, a plurality of spacers CS may be formed on the second insulating layer INS2. For example, the edge spacers CS_E and active spacers CS_A may be formed on the second insulating layer INS2.

According to embodiments, the spacers CS may be formed through a photolithography process. For example, an organic material layer may be applied on the second insulating layer INS2, and the organic material layer may be exposed. Thereafter, the organic material layer may be developed and cured to form the spacers CS.

Referring to FIGS. 7 and 11, in S740, the first layer BL and the second layer UL may be coupled to each other with a filling layer FIL interposed therebetween.

In the present operation, the filling layer FIL may be interposed between the first layer BL and the second layer UL, a sealing portion SEL may be provided along an outer area, and outer spacers CS_O may be on the sealing portion SEL. Thereafter, the first layer BL and the second layer UL may be vacuum-pressed to be adjacent to each other. Accordingly, the filling layer FIL may be compressed and may be spread and provided throughout a display area DA and a non-display area NDA. In some embodiments, the sealing portion SE may limit an area in which the filling layer FIL is provided and may seal other components. For example, a sealant may be provided along an edge of the display device DD and cured to form the sealing portion SEL. Accordingly, the display device DD according to the embodiment may be manufactured.

According to an embodiment of the present disclosure, the edge spacers CS_E and the active spacers CS_A may be on the second layer UL, and thus the filling layer FIL may be provided to a gap between the first layer BL and the second layer UL. In some embodiments, the edge spacers CS_E may be provided, and thus the filling layer FIL may be stably provided up to an area adjacent to the sealing portion SEL. Therefore, as described above, the filling layer FIL may be formed to fill the entire empty space between the first layer BL and the second layer UL, and the reliability of a process of manufacturing the display device DD may be improved.

By including a plurality of edge spacers on an edge bank, a display device according to embodiments of the present disclosure can be manufactured with improved reliability.

The effects according to embodiments are not limited to the contents described above, and more various effects are included in the present specification.

Although example embodiments and applications have been described herein, other embodiments and modifications may be derived from the above description. Accordingly, the present disclosure is not limited to such embodiments, but rather to the broader scope of the presented claims and various obvious modifications and equivalent arrangements.

What is claimed is:

1. A display device comprising:
a first layer which is on a first substrate comprising a display area and comprising banks protruding in a thickness direction of the first substrate, a color conversion layer in an area surrounded by the banks, and a color conversion portion that comprises quantum dots;
a second layer on a second substrate facing the first substrate;
a filling layer between the first layer and the second layer; and
a plurality of edge spacers on an edge bank which is any one of the banks.

2. The display device of claim 1, wherein the edge spacers space the edge bank apart from the second layer.

3. The display device of claim 1, wherein the edge spacers pass through the filling layer to support the second layer.

4. The display device of claim 1, wherein the first substrate comprises a non-display area that does not overlap the display area, and
the edge bank surrounds the display area and is in the non-display area.

5. The display device of claim 4, wherein the edge spacers are provided along an outer area of the edge bank.

6. The display device of claim 1, wherein the edge spacers are provided along a first line on the edge bank and a second line spaced apart from the first line.

7. The display device of claim 1, wherein the bank comprises an active bank in the display area, and
active spacers are on the active bank.

8. The display device of claim 7, wherein the active spacers and the edge spacers are formed at substantially the same time point.

9. The display device of claim 7, wherein the active spacers and the edge spacers comprise an acrylic-based material.

10. The display device of claim 1, wherein the color conversion layer comprises a first insulating layer that caps the color conversion unit,
the second layer comprises a color filter layer comprising color filters and a second insulating layer that caps the color filters, and
the filling layer has one surface in contact with the first insulating layer and the other surface in contact with the second insulating layer.

11. The display device of claim 10, wherein the edge spacers are in contact with the second insulating layer and the edge bank.

12. The display device of claim 1, wherein the first layer further comprises a light-emitting element layer comprising a light-emitting element, and
the color conversion layer converts a wavelength of light emitted from the light-emitting element.

13. A method of manufacturing a display device, the method comprising:
forming a first layer on a first substrate comprising a display area, wherein the first layer comprises banks protruding in a thickness direction of the first substrate and a color conversion layer in an area surrounded by the bank and comprising a color conversion portion that comprises quantum dots;
forming a second layer on a second substrate facing the first substrate;
forming a plurality of edge spacers on the second layer; and
forming a filling layer between the first layer and the second layer to couple the first layer and the second layer.

14. The method of claim 13, wherein the edge spacers space an edge bank, which is any one of the banks, apart from the second layer.

15. The method of claim 13, wherein the edge spacers pass through the filling layer to support the second layer.

16. The method of claim 13, wherein the first substrate comprises a non-display area that does not overlap the display area, and
an edge bank, which is one of the banks, surrounds the display area and is in the non-display area.

17. The method of claim 16, wherein the edge spacers are provided along an outer area of the edge bank.

18. The method of claim 16, wherein the bank comprises an active bank in the display area, and
active spacers are formed to overlap the active bank.

19. The method of claim 18, wherein the active spacers and the edge spacers are formed at substantially the same time point.

20. The method of claim 18, wherein the active spacers and the edge spacers comprise an acrylic-based material.
